(19) United States
(12) Patent Application Publication
(10) Pub. No.: US 2015/0044784 A1
(43) Pub. Date: Feb. 12, 2015

(54) MANUFACTURING METHOD FOR ELECTROLUMINESCENT ELEMENT

(71) Applicant: SHOWA DENKO K.K., Tokyo (JP)

(72) Inventors: Masahiro Suzuki, Tokyo (JP); Yusuke Yamazaki, Tokyo (JP)

(73) Assignee: SHOWA DENKO K.K., Minato-ku, Tokyo (JP)

(21) Appl. No.: 14/381,891

(22) PCT Filed: Feb. 28, 2013
(86) PCT No.: PCT/JP2013/055528

§ 371 Date: Aug. 28, 2014

(30) Foreign Application Priority Data
Feb. 29, 2012 (JP) 2012-044533

(51) Int. Cl. H01L 51/56; H01L 51/00

(52) U.S. Cl. CPC H01L 51/56; H01L 51/0031
USPC 438/7

(57) ABSTRACT

A manufacturing method for an electroluminescent element including a first manufacturing step of layering on a substrate, a first electroconductive layer, a dielectric layer in which plural contact holes are formed which penetrate therethrough, a second electroconductive layer electrically connected to the first electroconductive layer inside the contact holes and which fills the contact holes, a light-emitting layer, and a third electroconductive layer; a luminance distribution measurement step of applying a voltage to the first electroconductive layer and the third electroconductive layer of the electroluminescent element manufactured, causing the light-emitting layer to emit light, and the luminance distribution of the electroluminescent element is measured to obtain luminance unevenness information; and a second manufacturing step in which, on the basis of the luminance unevenness information, the density of the plural contact holes that penetrate the dielectric layer is adjusted to manufacture a second electroluminescent element having reduced luminance unevenness.

### TECHNICAL FIELD

The present invention relates to a manufacturing method for an electroluminescent element.

### BACKGROUND ART

Conventionally, as an electroluminescent element, there is known an organic layer including a light-emitting layer that is formed to be interposed between a cathode and an anode, in which the light-emitting layer in a region where the anode and the cathode overlap emits light by application of voltage between these electrodes.

In recent years, there has been a report on an organic electroluminescent element in which an organic light-emitting medium is provided between a first electrode (an anode or a cathode) and a semiconductor layer configured with a non-single-crystal material and a second electrode (a cathode or an anode) is electrically connected to an edge portion of the semiconductor layer, to thereby take out electroluminescent light emission from the semiconductor layer to the outside without substantially causing the first electrode and the second electrode face each other (refer to Patent Document 1).

### CITATION LIST

### Patent Literature

Patent Document 1: International Publication WO00/67531 Brochure

### DISCLOSURE OF INVENTION

### Technical Problem

By the way, in a case where an organic electroluminescent element having a structure described in Patent Document 1 is manufactured, it is required to form a semiconductor layer that is in contact with an electrode formed by fine patterning. Accordingly, it is possible to take out light emission to the outside without causing a cathode and an anode to face each other; however, it is difficult to form a smooth semiconductor layer, manufacturing steps become complex, and light emission in a light-emitting surface is apt to be non-uniform.

On the other hand, in the case of a conventional electroluminescent element, luminance unevenness occurs in some cases because of variations due to individual production line in the manufacturing steps, changes in material lots to be used, or the like.

An object of the present invention is to provide a manufacturing method for an electroluminescent element that is capable of reducing luminance unevenness in a light-emitting surface, to thereby obtain uniform light emission.

### Solution to Problem

According to the present invention, there is provided a manufacturing method for an electroluminescent element including: first manufacturing of an electroluminescent element (a first manufacturing step) that manufactures an electroluminescent element in which, on a substrate, a first electroconductive layer, a dielectric layer with plural contact holes passing through in a direction orthogonal to the substrate formed therein, a second electroconductive layer that is electrically connected to the first electroconductive layer inside the contact holes and fills the contact holes, a light-emitting layer and a third electroconductive layer are successively laminated; a luminance distribution measurement step that applies a voltage to the first electroconductive layer and the third electroconductive layer of the electroluminescent element manufactured in the first manufacturing step to cause the light-emitting layer to emit light, and measures luminance distribution of the electroluminescent element to obtain luminance unevenness information of the electroluminescent element; and second manufacturing of an electroluminescent element (a second manufacturing step) that adjusts a density of the plural contact holes passing through the dielectric layer based on the luminance unevenness information, to thereby reduce unevenness in luminance of the electroluminescent element.

Here, it is preferable that, in the luminance distribution measurement step, as the luminance unevenness information, an average luminance (L_{A}) of an entire measured portion of the electroluminescent element obtained by luminance distribution measurement of the electroluminescent element caused to emit light, and a highest luminance (L_{H}) and a lowest luminance (L_{L}) obtained by luminance distribution measurement of the electroluminescent element caused to emit light are measured.

It is preferable that, in the luminance distribution measurement step, based on the luminance unevenness information, a ratio ((L_{H}−L_{L})/L_{A}) of a difference (L_{H}−L_{L}) between a highest luminance (L_{H}) and a lowest luminance (L_{L}) obtained by luminance distribution measurement of the electroluminescent element caused to emit light to an average luminance (L_{A}) of an entire measured portion of the electroluminescent element obtained by luminance distribution measurement of the electroluminescent element caused to emit light is obtained as luminance unevenness.

It is preferable that, in the luminance distribution measurement step, in a case where the luminance unevenness is more than a threshold value of 0.3, the luminance unevenness information is fed back to the first manufacturing step.

It is preferable that, in the first manufacturing step and the second manufacturing step, the plural contact holes are formed so that a number of the contact holes is not less than 10² per a light-emitting region based on light emission in the light-emitting layer, and a ratio of a total area occupied by the plural contact holes to an area of the light-emitting region is not more than 0.2.

### Advantageous Effects of Invention

According to the present invention, it is possible to reduce luminance unevenness in a light-emitting surface, to thereby obtain uniform light emission.

### BRIEF DESCRIPTION OF DRAWINGS

FIG. 1 is a partial cross-sectional view illustrating a specific example of a light-emitting region of an electroluminescent element to which the exemplary embodiment is applied;

FIGS. 2A and 2B are diagrams illustrating a size of a contact hole;

FIGS. 3A to 3E are diagrams illustrating a specific example of a method for manufacturing the electroluminescent element;

FIG. 4 is a diagram illustrating a relation between a density of contact holes and luminance in the electroluminescent element that is emitting;

FIG. 5 is a flowchart illustrating a flow in a manufacturing method for the electroluminescent element, to which an exemplary embodiment is applied; and

FIGS. 6A to 6C are diagrams illustrating luminance distribution of the electroluminescent element.

### DESCRIPTION OF EMBODIMENTS

Hereinafter, exemplary embodiments according to the present invention will be described in detail. It should be noted that the present invention is not limited to the following exemplary embodiments, but may be practiced as various modifications within the scope of the gist of the invention. In other words, unless otherwise specified, dimensions, materials, shapes or relative arrangement of components described in the specific examples of the exemplary embodiments do not limit the scope of the present invention, but are merely descriptive specific examples. Further, each of the figures to be used indicates a specific example for illustration of each exemplary embodiment, and does not represent an actual size thereof. Sizes, positional relations and the like of the components illustrated in each drawing may exaggerate for making the description clearer in some cases. Moreover, in this specification, a phrase such as “above (on or over) a layer” is not only limited to a case of being formed on a layer in contact therewith, but also used to include a case of being formed above a layer with some separation, or a case including some layer being interposed between layers.

### <Electroluminescent Element>

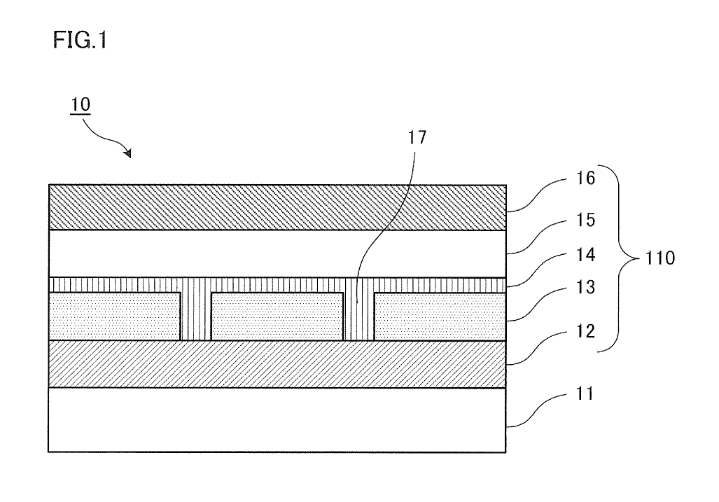

FIG. 1 is a partial cross-sectional view illustrating a specific example of a light-emitting region of an electroluminescent element 10, which is a subject for the exemplary embodiment.

The electroluminescent element 10 shown in FIG. 1 includes a substrate 11 and a lamination section 110 formed on the substrate 11. In the lamination section 110, there are laminated in order from the substrate 11 side: a first electroconductive layer 12 for injecting holes; a dielectric layer 13 having insulation properties; a second electroconductive layer 14 that covers the top surface of the dielectric layer 13; a light-emitting layer 15 that emits light upon coupling the holes and electrons; and a third electroconductive layer 16 for injecting the electrons.

As shown in FIG. 1, in the dielectric layer 13 of the electroluminescent element 10, plural contact holes 17 that pass through the dielectric layer 13 in a direction orthogonal to the substrate 11 are provided. Inside of each contact hole 17 is filled with a component constituting the second electroconductive layer 14.

In the exemplary embodiment, the contact hole 17 is filled only with the component of the second electroconductive layer 14. This connects the first electroconductive layer 12 and the second electroconductive layer 14 electrically inside the contact holes 17. Consequently, by applying the a voltage between the first electroconductive layer 12 and the third electroconductive layer 16, a voltage is applied between the second electroconductive layer 14 and the third electroconductive layer 16, to thereby cause the light-emitting layer 15 to emit light.

In this case, a surface of the light-emitting layer 15 on the substrate 11 side, a surface on the third electroconductive layer 16 side, which is opposite to the substrate 11 side, or both of these surfaces become the light-emitting surfaces from which light is taken out of the electroluminescent element 10. Moreover, in a case of being viewed from the surface on the substrate 11 side of the electroluminescent 10, or, in a case of being viewed from the surface on the third electroconductive layer 16 of the electroluminescent element 10, the light-emitting layer 15 emits light as a continuous light-emitting region.

It should be noted that, as another exemplary embodiment, the contact hole 17 may be filled with the components of the second electroconductive layer 14 and others by forming the second electroconductive layer 14 and further forming other components, such as the light-emitting layer 15, so as to contact the contact hole 17.

### (Substrate 11)

The substrate 11 serves as a support body that forms the first electroconductive layer 12, the dielectric layer 13, the second electroconductive layer 14, the light-emitting layer 15 and the third electroconductive layer 16. Usually, a material that satisfies mechanical strength required for a support body of the electroluminescent element 10 is used for the substrate 11.

The material for the substrate 11, in the case where the light is to be taken out from the substrate 11 side of the electroluminescent element 10 (that is, in the case where the surface of the substrate 11 side is the light-emitting surface from which the light is taken out), is preferably a material that is transparent to the wavelength of light emitted in the light-emitting layer 15. Specifically, in a case where the light emitted in the light-emitting layer 15 is visible light, for example: glasses such as soda glass and non-alkali glass; transparent plastics such as acrylic resins, methacrylic resins, polycarbonate resins, polyester resins and nylon resins; silicon and the like are provided.

It should be noted that, in the exemplary embodiment, “transparent to the wavelength of light emitted in the light-emitting layer 15” means that it is enough to transmit light with a constant wavelength range emitted from the light-emitting layer 15, and it is unnecessary to have optical transparency over the entire visible light region.

In a case where it is unnecessary to take out light from a surface on the substrate 11 side of the electroluminescent element 10, the material of the substrate 11 is not limited to the ones which are transparent, and opaque materials can be used. Specifically, in addition to the above-described materials, a material composed of: a simple substance such as copper, silver, gold, platinum, tungsten, titanium, tantalum or niobium; alloys thereof; stainless steel or the like; can be used.

### (First Electroconductive Layer 12)

Upon application of a voltage between the first electroconductive layer 12 and the third electroconductive layer 16, the first electroconductive layer 12 injects holes to the light-emitting layer 15 via the second electroconductive layer 14. In other words, in the exemplary embodiment, the first electroconductive layer 12 is an anode layer. A material used for the first electroconductive layer 12 is not particularly limited as long as the material has electric conductivity.

For example, conductive metal oxides, metals, alloys or the like can be provided. Here, as the conductive metal oxides, for example, indium tin oxide (ITO), indium zinc oxide (IZO), tin oxide, zinc oxide, and so on are provided. As the metals, stainless steel, copper, silver, gold, platinum, tungsten, titanium, tantalum, niobium, and the like are provided. Moreover, alloys including these metals can also be used. Of these materials, as the transparent materials used for forming a transparent electrode, ITO, IZO and tin oxide are preferable. In addition, a transparent conductive film composed of organic substances such as polyaniline or derivatives thereof, polythiophene or derivatives thereof and the like may be used.

The thickness of the first electroconductive layer 12 is, in the case where the surface on the substrate 11 side of the electroluminescent element 10 becomes the light-emitting surface, from which light is taken out, preferably 2 nm to 300 nm for obtaining high optical transparency. Moreover, in the case where there is no need to take out light from the substrate 11 side of the electroluminescent element 10, for example, the first electroconductive layer 12 may be formed with a thickness of 2 nm to 2 mm.

It should be noted that, for the substrate 11, a material same as that of the first electroconductive layer 12 can also be used. In this case, the substrate 11 may serve as the first electroconductive layer 12.

### (Dielectric Layer 13)

The dielectric layer 13 is laminated on the first electroconductive layer 12, and a material transparent to the light emitted in the light-emitting layer 15 is used.

As specific materials constituting the dielectric layer 13, for example, metal nitrides such as silicon nitride, boron nitride and aluminum nitride, and metal oxides such as silicon oxide and aluminum oxide are provided. Further, polymer compounds such as polyimide, polyvinylidene fluoride and parylene can also be used.

It is preferable that the thickness of the dielectric layer 13 does not exceed 1 μm for suppressing increase of electrical resistance between the first electroconductive layer 12 and the second electroconductive layer 14. It is more preferable to form the dielectric layer 13 with a thickness of 10 nm to 500 nm, and further preferable, to form with a thickness of 20 nm to 200 nm.

It should be noted that the shape of the contact hole 17 formed to pass through the dielectric layer 13 is not particularly limited, and the shape may be, for example, a cylindrical shape, a quadrangular prism shape, or the like.

Moreover, in the exemplary embodiment, the contact hole 17 is formed to pass through the dielectric layer 13 only; however, not limited to the exemplary embodiment. For example, the contact hole 17 may be formed to further pass through the first electroconductive layer 12.

### (Second Electroconductive Layer 14)

The second electroconductive layer 14 electrically contacts the first electroconductive layer 12 inside the contact hole 17 to inject the holes received from the first electroconductive layer 12 into the light-emitting layer 15. It is preferable that the second electroconductive layer 14 includes conductive metal oxides or conductive polymers. Specifically, the second electroconductive layer 14 is preferably a transparent conductive film, which has optical transparency, composed of conductive metal oxides, such as ITO, IZO and tin oxide, and organic substances, such as conductive polymer compounds. Moreover, in the exemplary embodiment, since the inside of the contact hole 17 is filled with a material to form the second electroconductive layer 14, it is preferable that the second electroconductive layer 14 is formed by coating for making it easy to form a film on an inner surface of the contact hole 17. Accordingly, from this point of view, it is especially preferable that the second electroconductive layer 14 is a transparent conductive film composed of organic substances, such as conductive polymer substances. It should be noted that the second electroconductive layer 14 and the first electroconductive layer 12 may be formed by use of the same material.

The thickness of the second electroconductive layer 14 is, in the case where the light is to be taken out from a surface on the substrate 11 side, preferably 2 nm to 300 nm for obtaining high optical transparency.

Moreover, in the exemplary embodiment, a layer for facilitating injection of the holes into the light-emitting layer 15 (for example, a hole injection layer, etc.) may be provided on a surface of the second electroconductive layer 14 that is brought into contact with the light-emitting layer 15. As such a layer, specifically, a layer of 1 nm to 200 nm composed of conductive polymers, such as phthalocyanine derivatives, polythiophene derivatives and the like, amorphous carbon, carbon fluoride, polyamine compound and the like, or a layer having an average thickness of not more than 10 nm composed of metal oxides, metal fluorides, organic insulating materials and the like, are provided.

### (Light-Emitting Layer 15)

The light-emitting layer 15 includes a light-emitting material that emits light by application of a voltage. As the light-emitting material contained in the light-emitting layer 15, any of organic materials and inorganic materials can be used. In the case of organic materials (luminescent organic materials), any of low-molecular compounds (luminescent low-molecular compounds) and polymer compounds (luminescent polymer compounds) can be used. As luminescent organic materials, phosphorescent organic compounds and metal complexes are preferred.

In the exemplary embodiment, from the viewpoint of improving the light-emitting efficiency of the light-emitting layer 15, it is particularly preferable to use cyclometalated complexes. As the cyclometalated complexes, for example, complexes of iridium, palladium, platinum and the like including ligands such as 2-phenylpyridine derivatives, 7, 8-benzoquinoline derivatives, 2-(2-thienyl)pyridine derivatives, 2-(1-naphthyl)pyridine derivatives, 2-phenylquinoline derivatives are provided. Of these, iridium complexes are especially preferred. The cyclometalated complexes may include ligands other than the ligands required to form the cyclometalated complexes.

As the luminescent polymer compounds, for example, there are provided: polymer compounds of a n-conjugated system, such as poly-p-phenylenevinylene (PPV) derivatives, polyfluorene derivatives and polythiophene derivatives; polymers introducing low-molecular pigments and tetraphenyldiamine or triphenylamine to a main chain or a side chain; and the like. The luminescent polymer compounds and the luminescent low-molecular compounds can be used in combination.

The light-emitting layer 15 includes the light-emitting material and a host material, and the light-emitting material is dispersed in the host material in some cases. It is preferable that the host material has charge transporting properties, and it is also preferable that the host material is a hole-transporting compound or an electron-transporting compound. It should be noted that, as the hole-transporting compound or the electron-transporting compound, a known material can be used.

The thickness of the light-emitting layer 15 is appropriately selected in consideration of charge mobility, balance of injected charge or interference of emitting light and the like, and is not particularly limited. In the exemplary embodiment, the thickness of the light-emitting layer 15 is preferably 1 nm to 1 μm, more preferably 2 nm to 500 nm, and especially preferably 5 nm to 200 nm.

### (Third Electroconductive Layer 16)

A voltage is applied between the third electroconductive layer 16 and the first electroconductive layer 12 and the electrons are injected from the third electroconductive layer 16 to the light-emitting layer 15. In other words, in the exemplary embodiment, the third electroconductive layer 16 is a cathode layer.

A material used for the third electroconductive layer 16 is, similar to that of the first electroconductive layer 12, not particularly limited as long as the material has electric conductivity. In the exemplary embodiment, it is preferable that the material has a low work function and is chemically stable. Specifically, Al, alloys of Al and alkali metals, such as AlLi, alloys of Al and Mg, such as MgAl alloy, alloys of Al and alkaline earth metals, such as AlCa, and the like can be provided as specific examples.

However, in the case where the light is to be taken out from the third electroconductive layer 16 side of the electroluminescent element 10 (namely, in the case where the surface of the third electroconductive layer 16 side becomes the light-emitting surface, from which the light is to be taken out), it is preferable to use a material transparent to the emitted light as the material for the third electroconductive layer 16, similar to the first electroconductive layer 12.

The thickness of the third electroconductive layer 16 is preferably 0.01 μm to 1 μm, and more preferably 0.05 μm to 0.5 μm.

In the exemplary embodiment, with intent to lower the barrier for the electron injection from the third electroconductive layer 16 into the light-emitting layer 15, to thereby increase the electron injection efficiency, a cathode buffer layer (not shown) may be provided adjacent to the third electroconductive layer 16. The cathode buffer layer is required to have a lower work function than the third electroconductive layer 16, and metallic materials may be suitably used therefor. As such metallic materials, for example, alkali metals (Na, K, Rb and Cs), Mg and alkaline earth metals (Sr, Ba and Ca), rare earth metals (Pr, Sm, Eu and Yb), one selected from fluoride, chloride and oxide of these metals and mixture of two or more selected therefrom can be used. The thickness of the cathode buffer layer is preferably 0.05 nm to 50 nm, more preferably 0.1 nm to 20 nm, and still more preferably 0.5 nm to 10 nm.

Moreover, in the exemplary embodiment, a layer other than the light-emitting layer 15 may be formed between the second electroconductive layer 14 and the third electroconductive layer 16. As such a layer, for example, a hole transporting layer, a hole blocking layer, an electron transporting layer or the like can be provided. Each layer is formed, in response to the function thereof, by use of a known charge transporting material or the like. Moreover, the thickness of each layer is appropriately selected in consideration of charge mobility, balance of injected charge or interference of emitting light and the like, and is not particularly limited. In the exemplary embodiment, the thickness of each layer is preferably 1 nm to 500 nm, and more preferably, 5 nm to 200 nm.

### (Contact Hole 17)

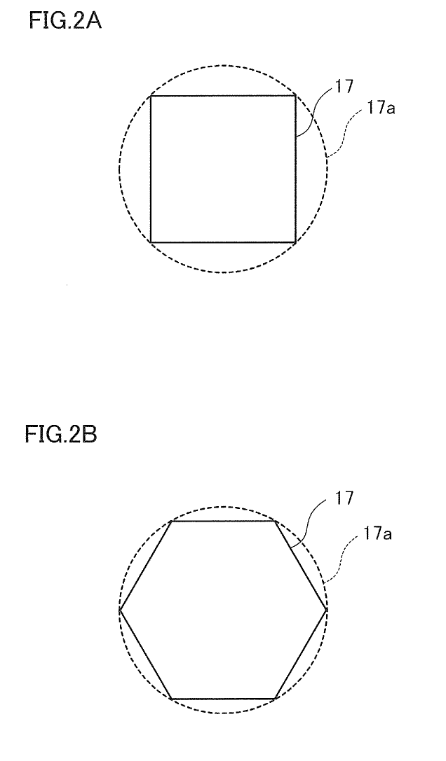

FIGS. 2A and 2B are diagrams illustrating a size of the contact hole 17. FIG. 2A shows, for example, a case in which the contact hole 17 has a cross-sectional shape of a square as the light-emitting surface of the light-emitting layer 15 is viewed in a plan view from a perpendicular direction with respect to the substrate 11, and FIG. 2B shows a case in which the cross-sectional shape thereof is a hexagon. In the exemplary embodiment, as shown in FIGS. 2A and 2B, the size of the contact hole 17 is represented by use of a diameter of a minimum circle 17a enclosing the above-described shape of the contact hole 17 (the minimum enclosing circle) in the case of viewing the contact hole 17 in a plan view.

In the exemplary embodiment, from the viewpoint of increasing the area of the light-emitting layer 15 to be formed on the dielectric layer 13 and luminance of the electroluminescent element 10, the size of the contact hole 17 is preferably as small as possible as long as electrical connection between the first electroconductive layer 12 and the second electroconductive layer 14 is fully available.

From the viewpoint like this, the diameter of the minimum enclosing circle 17a is preferably 0.01 μm to 2 μm. For example, in the case where the contact hole 17 has a cylindrical shape, the diameter of the cylinder is preferably 0.01 μm to 2 μm.

In the exemplary embodiment, in the case where the dielectric layer 13 is viewed in the plan view from the light-emitting surface side of the light-emitting layer 15, the ratio of the total area occupied by the plural contact holes 17 to the area of the light-emitting region is preferably not more than 0.2, and especially preferably 0.001 to 0.1. In the case where the ratio of the total area occupied by the contact holes 17 is within the above-described range, it becomes easy to correct luminance unevenness.

In the exemplary embodiment, the number of the contact holes 17 to be formed in one light-emitting region is at least not less than 10², and preferably not less than 10⁴. However, it is preferable that the number of contact holes 17 is such that, as described above, the ratio of the total area of the contact holes 17 in the light-emitting region surface is preferably in the range of not more than 0.2. It should be noted that, since FIG. 1 is a schematic view, it is not necessarily assumed to represent the ratio of each value.

In the exemplary embodiment, the plural contact holes 17 may be distributed uniformly or non-uniformly in the light-emitting region with a desired light-emitting mode. Moreover, the plural contact holes 17 in the light-emitting region may be arranged regularly or irregularly. However, in view of manufacturing, it is preferable that the plural contact holes 17 are arranged regularly. As a specific example of regular arrangement, for example, an arrangement of a cubic lattice or a hexagonal lattice can be provided. With such an arrangement, in the electroluminescent element 10 to which the exemplary embodiment is applied, a light-emitting portion is formed on the smooth dielectric layer 13, and it is possible to increase uniformity in light emission in the light-emitting region.

It should be noted that, in the above-described specific example, description was given of the case where the first electroconductive layer 12 was assumed to be the anode layer and the third electroconductive layer 16 was assumed to be the cathode layer; however, the specific example is not limited thereto, and the first electroconductive layer 12 may be the cathode layer and the third electroconductive layer 16 may be the anode layer.

### <Manufacturing Method for Electroluminescent Element>

Next, description will be given of a manufacturing method for an electroluminescent element, while the electroluminescent element 10 shown in FIG. 1 is taken as a specific example.

### (First Electroluminescent Element Manufacturing (Hereinafter, Referred to as “First Manufacturing Step”))

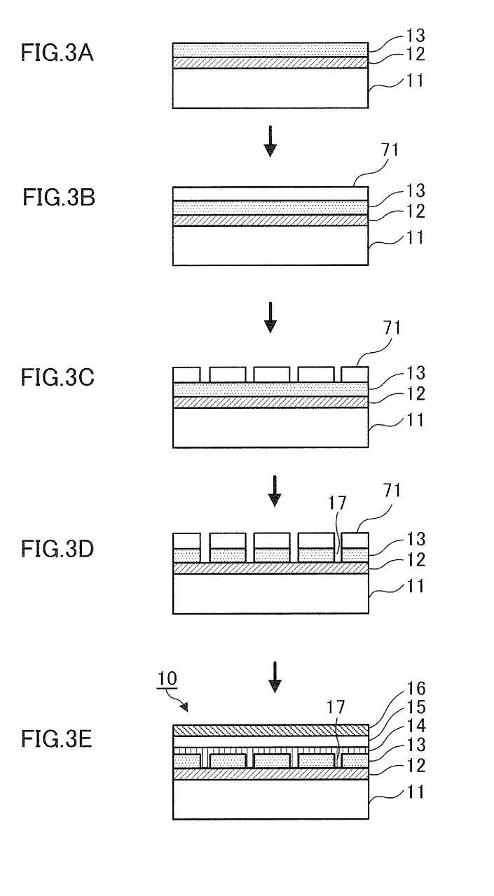

FIGS. 3A to 3E are diagrams for illustrating the method for manufacturing the electroluminescent element 10.

First, as shown in FIG. 3A, on the substrate 11, the first electroconductive layer 12 and the dielectric layer 13 are successively laminated. For forming these layers, a resistance heating deposition method, an electron beam deposition method, a sputtering method, an ion plating method, a CVD method or the like can be used. Alternatively, if a coating film-forming method (that is, a method for applying a target material solved in a solvent to the substrate and then drying the same) is applicable, the layers can be formed by a spin coating method, a dip coating method, an ink-jet printing method, a printing method, a spray-coating method and a dispenser-printing method or the like.

Next, the contact holes 17 are formed in the dielectric layer 13. For forming the contact holes 17, a method using photolithography may be provided, for example.

As shown in FIG. 3B, first, a photoresist solution is applied on the dielectric layer 13 and then an excess photoresist solution is removed by spin coating or the like to form a photoresist layer 71.

Subsequently, as shown in FIG. 3C, the photoresist layer 71 is covered with a mask, in which a predetermined pattern for forming the contact holes 17 is rendered, and is exposed with ultraviolet (UV), an electron beam (EB) or the like. Here, by performing same magnification exposure (for example, in a case of contact exposure or proximity exposure), a pattern of the contact holes 17 with the same magnification as the mask pattern can be formed. Moreover, if reduced exposure (for example, in a case of exposure using a stepper) is performed, a pattern of the contact holes 17 which is reduced with respect to the mask pattern can be formed. Next, unexposed portions of the photoresist layer 71 are removed by use of a developing solution, and thereby pattern portions of the photoresist layer 71 are removed and part of the dielectric layer 13 is exposed.

Next, as shown in FIG. 3D, the exposed portions of the dielectric layer 13 are removed by etching to form the contact holes 17. In this case, part of the first electroconductive layer 12 provided below the dielectric layer 13 may also be removed by etching. Either dry etching or wet etching can be used as the etching. Reactive ion etching (RIE) or inductive coupling plasma etching is provided as the dry etching. Moreover, as the wet etching, a method of immersion in diluted hydrochloric acid or diluted sulfuric acid is provided. It should be noted that, in performing etching, by controlling etching conditions (for example, a process time, gases to be used, pressure, and a substrate luminance), the layers to be penetrated by the contact holes 17 can be selected.

Moreover, the contact holes 17 can also be formed by a method of nanoimprinting. Specifically, after forming the photoresist layer 71, a mask in which convex patterns are rendered is pressed against the surface of the photoresist layer 71 with pressure. By applying heat and/or light to the photoresist layer 71 in this state, the photoresist layer 71 is cured. Next, the mask is removed, and thereby the pattern, which is a pattern of the contact holes 17 corresponding to the convex patterns on the mask, is formed on a surface of the photoresist layer 71. Subsequently, the contact holes 17 can be formed by performing the aforementioned etching.

Next, as shown in FIG. 3E, on the dielectric layer 13, on which the contact holes 17 have been formed, the second electroconductive layer 14, the light-emitting layer 15 and the third electroconductive layer 16 are successively laminated. These layers are formed by a method same as that for forming the first electroconductive layer 12 or the dielectric layer 13. It should be noted that, in the exemplary embodiment, it is preferable to form the second electroconductive layer 14 by a coating film-forming method. By employing the coating film-forming method, it is possible to fill the material constituting the second electroconductive layer 14 inside the contact holes 17 with ease.

### (Luminance Distribution Measurement Step)

Subsequently, by causing the electroluminescent element 10 manufactured in the first manufacturing step to emit light, luminance distribution is measured. Specifically, a voltage is applied to the electroluminescent element 10 by a DC power supply to cause the electroluminescent element 10 to emit light at a predetermined average luminance, to thereby measure the luminance distribution by use of a predetermined luminance meter. The more the sampling number of the electroluminescent element 10 for measuring the luminance distribution, the more accurately the luminance distribution can be measured, and preferably, average luminance distribution is obtained. In the exemplary embodiment, it is preferable to measure not less than 10 electroluminescent elements 10, and more preferable to measure all of the electroluminescent elements 10.

By measuring the luminance distribution, as luminance unevenness information, luminance in each part of the electroluminescent element 10 that has been caused to emit light (hereinafter, also referred to as “partial luminance”), the highest luminance (L_{H}), the lowest luminance (L_{L}) and the average luminance (L_{A}) are obtained.

Next, based on the luminance unevenness information obtained by measurement of the luminance distribution, luminance unevenness of the electroluminescent element 10 that has been caused to emit light is calculated by the following mathematical expression (1).

Luminance unevenness=(L_{H}−L_{L})/L_{A} (1)

Subsequently, in a case where the luminance unevenness calculated by the mathematical expression (1) is larger than a predetermined threshold value, the luminance unevenness information of the electroluminescent element 10 manufactured in the first manufacturing step is fed back to the following manufacturing (the second manufacturing step). It should be noted that, in ordinary illumination, to make the luminance unevenness less noticeable to the naked eye, the threshold value is preferably not more than 0.3, and more preferably, not more than 0.2. Further, in a case of uses with sensitivity to luminance unevenness (for example, some design-centric illumination or the like), it is possible to set the threshold value to not more than 0.1, or further, not more than 0.05, in the exemplary embodiment.

Hereinafter, as the exemplary embodiment, description will be given with an example in which the threshold value of the luminance unevenness is set to 0.03.

### (Second Electroluminescent Element Manufacturing (Hereinafter, Referred to as “Second Manufacturing Step”))

In the second manufacturing step, similar to the above-described first manufacturing step, the first electroconductive layer 12 and the dielectric layer 13 are successively laminated on the substrate 11, and subsequently, plural contact holes 17 are formed in the dielectric layer 13 by photolithography.

In the second manufacturing step, based on the measurement value of luminance that has been fed back as the luminance unevenness information of the electroluminescent element 10 manufactured in the first manufacturing step, a density of the plural contact holes 17 is adjusted so that the luminance distribution becomes uniform.

The partial luminance of the emitting electroluminescent element 10 is susceptible to the density of the contact holes 17 more than the size, shape or the like thereof, and accordingly, to control the luminance distribution, it is preferable to control the density of the plural contact holes 17 that pass through the dielectric layer 13.

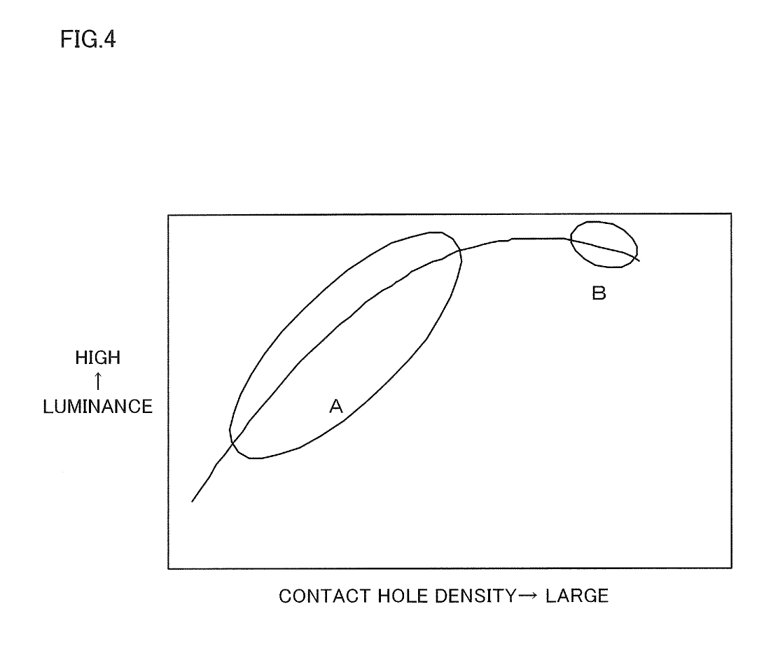

FIG. 4 is a diagram illustrating a relation between the density of the contact holes 17 and luminance of the electroluminescent element 10 that is emitting.

In FIG. 4, region A indicates a region where, as the density of the contact holes 17 increases, the partial luminance of the electroluminescent element 10 also increases. Moreover, region B indicates a region where, as the density of the contact holes 17 increases, the partial luminance of the electroluminescent element 10 decreases. Conditions for making region A or region B like these can be obtained by measuring a relation between the density of the contact holes 17 and the luminance in advance by a preliminary experiment.

To adjust the density of the contact holes 17 to make the luminance distribution uniform, for example, in region A, based on the measurement value of luminance that has been fed back as the luminance unevenness information of the electroluminescent element 10 manufactured in the first manufacturing step, when the contact holes 17 are formed, operations of decreasing the density of the contact holes 17 in a portion where the luminance is higher than the average luminance (L_{A}) and increasing the density of the contact holes 17 in a portion where the luminance is lower than the average luminance (L_{A}) are carried out.

Similarly, in region B, based on the measurement value of luminance that has been fed back as the luminance unevenness information, when the contact holes 17 are formed, operations of increasing the density of the contact holes 17 in a portion where the luminance is higher than the average luminance (L_{A}) and decreasing the density of the contact holes 17 in a portion where the luminance is lower than the average luminance (L_{A}) are carried out.

It should be noted that, in an intermediate region between region A and region B, changes in the luminance is not so much with respect to changes in the density of the contact holes 17; however, although a region is such a region at the beginning, the region becomes region A by continuously decreasing the density of the contact holes 17, and conversely, the region becomes region B by continuously increasing the density of the contact holes 17; therefore, it is possible to perform luminance control.

In this manner, the luminance unevenness information obtained by the luminance distribution measurement is fed back to the second manufacturing step, which is the next step, to thereby perform adjustment to increase or decrease the density of the contact holes 17 in specific portions in the electroluminescent element 10 to be manufactured.

Specifically, for example, when the photoresist layer coated to be formed on the dielectric layer 13 is exposed by a stepper exposure device, the exposed surface is divided (for example, into a lattice pattern, a honeycomb pattern or the like) and the scale of the mask is changed in each divided portion, to thereby perform exposure while adjusting the density of the contact holes 17. At this time, the density of the contact holes 17 is adjusted in accordance with the luminance at a position, which corresponds to the above-described divided exposed portion, on the electroluminescent element 10 measured in the first manufacturing step.

It should be noted that the above-described division is preferably performed in a tetragonal lattice pattern, which is easily handled. The division number is not particularly limited. However, it is preferable to make a division so that the size of a region is of the order of 0.1 mm² to 10 cm², and it is more preferable to make a division so that the size of a region is of the order of 1 mm² to 1 cm². By making a division into such a size, the luminance control is performed with ease.

A range in which the density of the contact holes 17 is increased or decreased is, usually, in a range in which the luminance unevenness obtained by the mathematical expression (1) does not diverge, but converges, preferably increased or decreased within a width of the order that is the same as the ratio of a difference between the average luminance of the entire electroluminescent element 10 and the luminance of the specific portion to 1/10 thereof (hereinafter, referred to as “feedback rate of 1 to 1/10”). For example, in a case where, within region A in FIG. 4, the partial luminance of a portion is 10% higher than the average luminance, the density of the contact holes 17 in the portion may be preferably decreased by steps of 1% to 10%. By adjusting the density of the contact holes 17 in the range like this, the luminance unevenness of the electroluminescent element 10 is averaged.

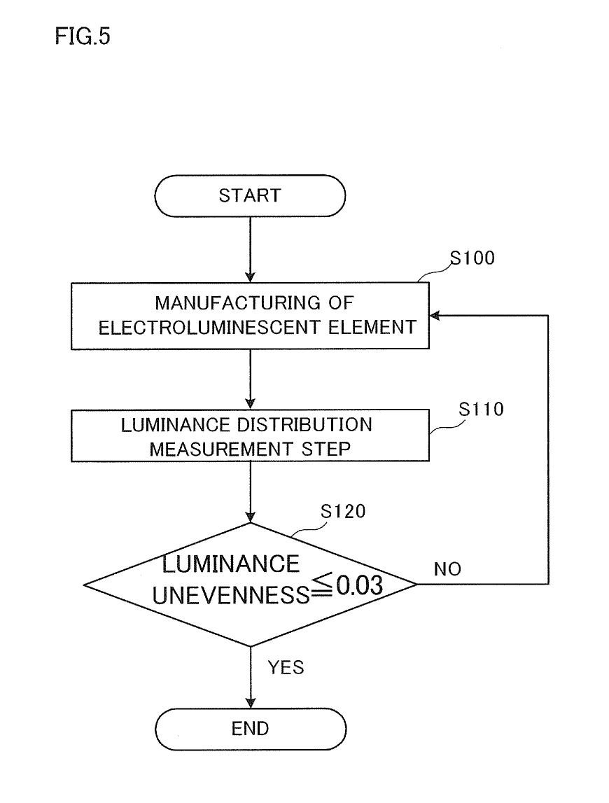

FIG. 5 is a flowchart illustrating a flow in the manufacturing method for the electroluminescent element 10, to which an exemplary embodiment is applied.

In the manufacturing method for the electroluminescent element, as the first manufacturing step, the electroluminescent element 10, in which, on the substrate 11, the first electroconductive layer 12 (anode), the dielectric layer 13 with the plural contact holes 17 formed therein, the second electroconductive layer 14 that is electrically connected to the first electroconductive layer 12 inside the contact holes 17 and fills the contact holes, the light-emitting layer 15 and the third electroconductive layer 16 (cathode) are successively laminated, is manufactured (step 100).

Subsequently, as the luminance distribution measurement step, the electroluminescent element 10 manufactured in the first manufacturing step is caused to emit light, to thereby measure the luminance distribution of the electroluminescent element 10 and obtain the luminance unevenness information (step 110). The luminance unevenness information includes the highest luminance (L_{H}), the lowest luminance (L_{L}) and the average luminance (L_{A}) of the electroluminescent element 10 that has been caused to emit light. Then, based on the obtained luminance unevenness information, by the above-described mathematical expression (1), luminance unevenness of the electroluminescent element 10 that has been caused to emit light is calculated.

Next, it is determined whether or not the luminance unevenness calculated in the luminance distribution measurement step exceeds the predetermined threshold value (in the exemplary embodiment, set to 0.03) (step 120). In the case where the luminance unevennesss exceeds the threshold value (0.03) (NO), the electroluminescent element 10 is manufactured while the luminance unevenness information is fed back to the first manufacturing step and the density of the plural contact holes 17 passing through the dielectric layer 13 is adjusted (the second manufacturing step).

Then, in the luminance distribution measurement step again, the luminance distribution of the electroluminescent element 10 manufactured in the second manufacturing step is measured to determine whether or not the obtained luminance unevenness exceeds the threshold value (0.03), and in the case where the luminance unevenness exceeds the threshold value, the luminance unevenness information is fed back to the first manufacturing step, and the step of adjusting the density of the contact holes 17 is repeated until the luminance unevenness becomes not more than the threshold value (0.03).

With the above steps, the electroluminescent element 10 can be manufactured. It should be noted that, in the case where the electroluminescent element 10 is stably used for long periods, it is preferable to mount a protective layer or a protective cover (not shown) for protecting the electroluminescent element 10 from the outside. As the protective layer, polymer compounds, metal oxides, metal fluorides, metal borides, or silicon compounds such as silicon nitrides and silicon oxides can be used. Then, a lamination thereof can also be used. As the protective cover, glass plates, plastic plates with a surface treated with low hydraulic permeability, metals or the like can be used.

The electroluminescent element 10 to which the exemplary embodiment is applied can be used in, for example, a display device, an illumination device and the like.

Though not particularly limited, as the display device, a so-called passive matrix display device is provided.

Moreover, usually, by a lighting circuit including a DC power supply and a control circuit inside thereof, an illumination device supplies a current between the first electroconductive layer 12 and the third electroconductive layer 16 of the electroluminescent element 10, to thereby cause the light-emitting layer 15 to emit light. The light emitted in the light-emitting layer 15 is taken to the outside through the substrate 11, and is utilized for illumination.

### EXAMPLES

Hereinafter, the present invention will be described in further detail based on Examples. However, the present invention is not limited to the following Examples.

### (Preparation of Electroluminescent Element)

With the following method, the electroluminescent element 10 was prepared.

First, on a glass substrate made of quartz glass (the substrate 11: 25 mm per side, a thickness of 1 mm), the first electroconductive layer 12 configured with an ITO film with a thickness of 150 nm and the dielectric layer 13 configured with a silicon dioxide (SiO₂) film with a thickness of 50 nm were formed by successive lamination by use of a sputtering device (E-401s manufactured by Canon ANELVA Corporation). Subsequently, on the dielectric layer 13, a photoresist (AZ1500 manufactured by AZ Electronic Materials) layer 71 with a thickness of about 1 μm was formed by a spin coating method.

Subsequently, with a quartz (with a thickness of 3 mm) as a base material, a mask A corresponding to a pattern in which circles were arranged on hexagonal lattices was prepared, and the photoresist layer 71 was exposed on a scale of 1/5 by use of a stepper exposure device (model NSR-1505i6 manufactured by Nikon Corporation). Next, the exposed photoresist layer 71 was developed with 1.2% aqueous solution of tetramethyl ammonium hydroxide ((TMAH):(CH₃)₄NOH) for patterning the photoresist layer 71, and thereafter, heat at a temperature of 130° C. was applied for 10 minutes (post-baking process).

Next, by a reactive ion etching device (RIE-2001P manufactured by SAMCO Inc.), a dry etching process was applied on the photoresist layer 71 by causing a reaction for 18 minutes with CHF₃ as a reactant gas under conditions of a pressure of 0.3 Pa and output bias/ICP=50/100 (W). Next, the residue of the photoresist was removed by a photoresist removing solution, and thereby the plural contact holes 17 passing through the dielectric layer 13 configured with the SiO₂ layer were formed. The contact hole 17 had a cylindrical shape with a diameter of 1 μm, and the contact holes 17 were arranged in a hexagonal lattice with a 4-μm pitch on an entire surface of the dielectric layer 13.

Subsequently, on the dielectric layer 13, an aqueous suspension (1.5% by mass in content) of a mixture of poly(3,4-ethylendioxythiophene) (PEDOT) and polystyrene sulfonate (PSS) (PEDOT:PSS=1:6 in mass ratio) was applied by the spin coating method (spin rate: 3000 rpm), and being left under a nitrogen atmosphere at the temperature of 140° C. for an hour to be dried, and accordingly, the second electroconductive layer 14 with a thickness of 20 nm was formed on the dielectric layer 13.

Next, on the second electroconductive layer 14, a xylene solution of 1.1% by mass in content of a compound (A) indicated below was applied by the spin coating method (spin rate: 3000 rpm), and left under a nitrogen atmosphere at the temperature of 210° C. for an hour to be dried, and thereby a hole transport layer with a thickness of 20 nm was formed.

Subsequently, on the above-described hole transport layer, a xylene solution (a solid content concentration is 1.6% by mass) including a compound (B), a compound (C) and a compound (D) indicated below with mass ratio of 9:1:90 was applied by the spin coating method (spin rate: 3000 rpm), and left under a nitrogen atmosphere at the temperature of 140° C. for an hour to be dried, and thereby the light-emitting layer 15 with a thickness of 50 nm was formed.

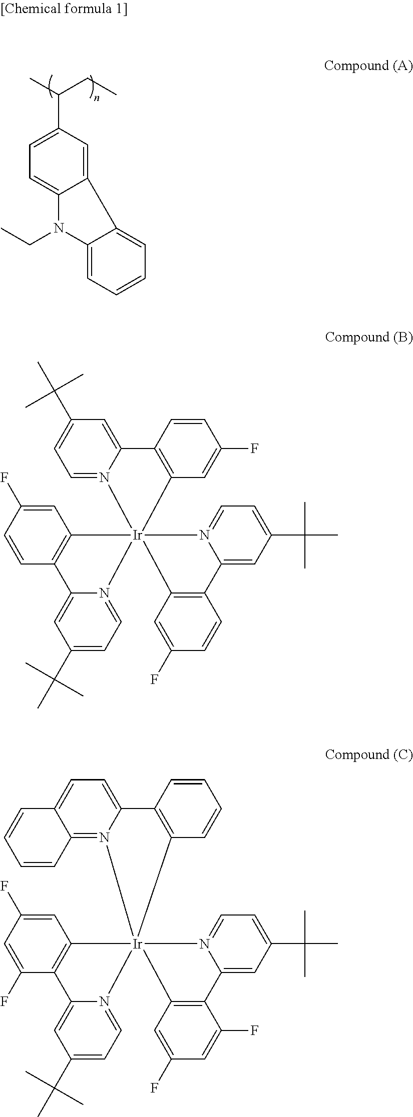

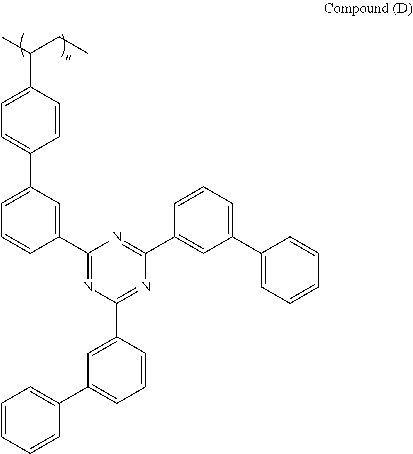

Further, by a deposition method, on the above-described light-emitting layer 15, the cathode buffer layer composed of sodium fluoride (with a thickness of 4 nm) and the third electroconductive layer 16 composed of aluminum (with a thickness of 130 nm) were formed, to thereby prepare the electroluminescent element 10.

The prepared electroluminescent element 10 has a light-emitting surface on the substrate 11 side of the light-emitting layer 15 and includes one continuous light-emitting region. Moreover, when the electroluminescent element 10 was observed (viewed in a plan view) from the light-emitting surface side, the number of plural contact holes 17 in the above-described light-emitting region was about 2×10⁷. The ratio of the total area occupied by the plural contact holes 17 to the area of the light-emitting region was 0.057.

It should be noted that the obtained electroluminescent element 10 was an element having properties included in the above-described region A.

### (Measurement of Luminance Distribution)

Subsequently, each of these 10 electroluminescent elements 10 was caused to emit light, and the luminance distribution was measured. In the measurement of luminance distribution, in conformity to each exposed portion by a stepper exposure device to be described later, the light-emitting surface of the electroluminescent element 10 was divided into portions of 5 mm square, and the luminance of each portion was recorded. By measurement of luminance distribution, the partial luminance of the above-described each portion of the electroluminescent element 10 that was caused to emit light, the average luminance (L_{A}) of the entire measured portions, the highest luminance (L_{H}) and the lowest luminance (L_{L}) obtained by luminance distribution measurement of the electroluminescent element 10 that was caused to emit light was obtained as the luminance unevenness information.

Subsequently, based on the luminance unevenness information obtained by the luminance distribution measurement of the 10 electroluminescent elements 10 prepared in the first one batch, the luminance unevenness obtained by the above-described mathematical expression (1) (luminance unevenness=(L_{H}−L_{L})/L_{A}) was 0.4. It should be noted that the luminance unevenness is an average value of the measurement results in the 10 electroluminescent elements 10.

### (Feedback of Luminance Unevenness Information)

The luminance variation obtained by the luminance distribution measurement of the 10 electroluminescent elements 10 prepared in the first one batch was 0.4, which is larger than the threshold value of the luminance unevenness (0.03).

Accordingly, the luminance unevenness information obtained by the above-described luminance distribution measurement (the partial luminance, L_{H}, L_{L} and L_{A}) was fed back to the manufacturing step of the electroluminescent element 10, and the electroluminescent element 10 was manufactured while adjusting the density of the plural contact holes 17 at the feedback rate 1 so that the luminance distribution of the electroluminescent element 10 that was caused to emit light became uniform.

Specifically, the photoresist layer was coated and formed on the dielectric layer 13, and subsequently, by use of a predetermined mask, exposure was performed by a stepper exposure device while adjusting the density of the contact holes 17 per each portion of 5 mm square. Adjustment of the density of the contact holes was carried out by changing the scale of the mask based on the above-described luminance recorded corresponding to the exposed portion.

The above-described operation was repeated until the luminance unevenness based on the luminance unevenness information per each batch became not more than the threshold value (0.03), and accordingly, the electroluminescent element 10 was manufactured. As a result, the luminance unevenness became not less than 0.03 in the third batch.

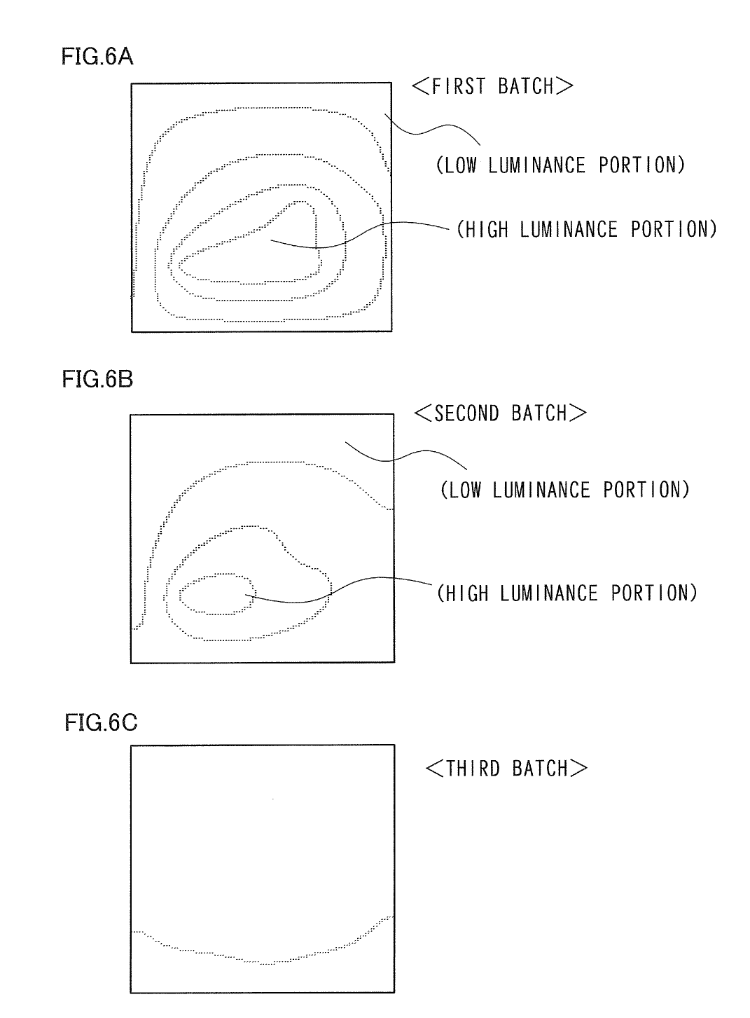

Moreover, in FIGS. 6A to 6C, diagrams illustrating the luminance distribution of the electroluminescent element 10 were shown.

FIG. 6A is a diagram illustrating the luminance distribution of the electroluminescent element 10 in the first batch. As shown in FIG. 6A, in the electroluminescent element 10 that is caused to emit light, it is learned that a high-luminance portion of the highest luminance is measured at a center portion and a low-luminance portion of the lowest luminance is measured at a peripheral portion, and the luminance distribution is generated between the high-luminance portion and the low-luminance portion.

FIG. 6B is a diagram illustrating the luminance distribution of the electroluminescent element 10 in the second batch. It is learned that, in comparison with the first batch (FIG. 6A), the luminance distribution is decreased.

FIG. 6C is a diagram illustrating the luminance distribution of the electroluminescent element 10 in the third batch. It is learned that, in comparison with the second batch (FIG. 6B), the luminance distribution is further decreased.

### REFERENCE SIGNS LIST

10 . . . Electroluminescent element
11 . . . Substrate
12 . . . First electroconductive layer
13 . . . Dielectric layer
14 . . . Second electroconductive layer
15 . . . Light-emitting layer
16 . . . Third electroconductive layer
17 . . . Contact hole
17a . . . Minimum enclosing circle
110 . . . Lamination section

1. A manufacturing method for an electroluminescent element comprising:
first manufacturing of an electroluminescent element (a first manufacturing step) that manufactures an electroluminescent element in which, on a substrate, a first electroconductive layer, a dielectric layer with a plurality of contact holes passing through in a direction orthogonal to the substrate formed therein, a second electroconductive layer that is electrically connected to the first electroconductive layer inside the contact holes and fills the contact holes, a light-emitting layer and a third electroconductive layer are successively laminated;
a luminance distribution measurement step that applies a voltage to the first electroconductive layer and the third electroconductive layer of the electroluminescent element manufactured in the first manufacturing step to cause the light-emitting layer to emit light, and measures luminance distribution of the electroluminescent element to obtain luminance unevenness information of the electroluminescent element; and
second manufacturing of an electroluminescent element (a second manufacturing step) that adjusts a density of the plurality of contact holes passing through the dielectric layer based on the luminance unevenness information, to thereby reduce unevenness in luminance of the electroluminescent element.

2. The manufacturing method for an electroluminescent element according to claim 1, wherein, in the luminance distribution measurement step, as the luminance unevenness information, an average luminance (L_{A}) of an entire measured portion of the electroluminescent element obtained by luminance distribution measurement of the electroluminescent element caused to emit light, and a highest luminance (L_{H}) and a lowest luminance (L_{L}) obtained by luminance distribution measurement of the electroluminescent element caused to emit light are measured.

3. The manufacturing method for an electroluminescent element according to claim 1, wherein, in the luminance distribution measurement step, based on the luminance unevenness information, a ratio ((L_{H}−L_{L})/L_{A}) of a difference (L_{H}−L_{L}) between a highest luminance (L_{H}) and a lowest luminance (L_{L}) obtained by luminance distribution measurement of the electroluminescent element caused to emit light to an average luminance (L_{A}) of an entire measured portion of the electroluminescent element obtained by luminance distribution measurement of the electroluminescent element caused to emit light is obtained as luminance unevenness.

4. The manufacturing method for an electroluminescent element according to claim 3, wherein, in the luminance distribution measurement step, in a case where the luminance unevenness is more than a threshold value of 0.3, the luminance unevenness information is fed back to the first manufacturing step.

5. The manufacturing method for an electroluminescent element according to claim 1, wherein, in the first manufacturing step and the second manufacturing step, the plurality of contact holes are formed so that a number of the contact holes is not less than 10² per a light-emitting region based on light emission in the light-emitting layer, and a ratio of a total area occupied by the plurality of contact holes to an area of the light-emitting region is not more than 0.2.
